(19) United States
(12) Patent Application Publication
(10) Pub. No.: US 2004/0130027 A1
(43) Pub. Date: Jul. 8, 2004

(54) IMPROVED FORMATION OF POROUS INTERCONNECTION LAYERS

(75) Inventors: Shyng-Tsong Chen, Patterson, NY (US); Stephen M. Gates, Ossining, NY (US); Jeffrey C. Hedrick, Montvale, NJ (US); Kelly Malone, Poughkeepsie, NY (US); Satyanarayana Nitta, Poughquag, NY (US); Christy S. Tyberg, Mahpoc, NY (US)

Correspondence Address: FREDERICK W. GIBB, III, MCGINN & GIBB, PLLC, 2568-A RIVA ROAD, SUITE 304, ANNAPOLIS, MD, 21401, US

(73) Assignee: International Business Machines Corporation, Armonk, NY

(21) Appl. No.: 10/338,105

(22) Filed: Jan. 7, 2003

(51) Int. Cl. H01L 23/48; H01L 23/52; H01L 29/40

(52) U.S. Cl. 257/758

(57) ABSTRACT

A method and structure for forming an integrated circuit structure is disclosed that forms at least one first layer comprising logical and functional devices and forms at least one interconnection layer above the first layer. The interconnection layer is adapted to form electrical connections between the logical and functional devices. The interconnection layer is made by first forming a dielectric layer. The dielectric layer includes a first material and a second material, wherein the second material is less stable at manufacturing environmental conditions (e.g., the processing conditions discussed below) than the first material. The “second material” comprises a porogen and the “first material” comprises a matrix polymer. The invention then forms conductive features in the dielectric layer and removes (e.g., by heating) the second material from the dielectric layer to create air pockets in the interconnection layer where the second material was positioned.

### BACKGROUND OF THE INVENTION

1. Field of the Invention

The present invention generally relates to a method and structure for improved formation of porous interconnection layers that removes porogen from low K interconnection layer after the formation of conductive features, to prevent voids and short circuits.

2. Description of the Related Art

Integrated circuit processing can be generally divided into front end of line (FEOL) and back and of line (BEOL) processes. During FEOL processing, the various logical and functional devices are manufactured. The FEOL processing will generally make a many layers of logical and functional devices. Layers of interconnections are formed above these logical and functional layers during the BEOL processing to complete the integrated circuit structure. Therefore, BEOL processing generally involves the formation of insulators and conductive wiring and contacts.

Recently, insulators (dielectrics) that have a lower dielectric constant (and are softer) are replacing older, harder, higher dielectric constant insulators. Lower dielectric constant materials generally have a dielectric constant below 3.0 and include polymeric low K dielectrics commercial products such as SiLK®, available from Dow Chemical Company, NY, USA, FLARE®, available from Honeywell, NJ, USA, microporous glasses such as Nanoglass® (Porous SiO₂), available from Honeywell, Inc., NJ, USA, as well as Black Diamond (Carbon-doped SiO₂), available from Applied Material, CA, USA; Coral (Silicon carbide based dielectrics), available from Novellus Systems, Inc., CA, USA; and Xerogel, available from Allied Signal, NJ, USA. These lower dielectric constant insulators are referred to as “low-k” dielectrics. These low-k dielectrics are advantageous because they decrease overall capacitance, which increases device speed and allows lower voltages to be utilized (making the device smaller and less expensive). Metals (such as copper, tungsten, etc.) are generally used as a wiring and connections in the BEOL interconnection layers.

### SUMMARY OF THE INVENTION

The invention provides a method of forming an integrated circuit structure that forms at least one first layer comprising logical and functional devices and forms at least one interconnection layer above the first layer. The interconnection layer is adapted to form electrical connections between the logical and functional devices.

The interconnection layer is made by first forming a dielectric layer. The dielectric layer includes a first material and a second material, wherein the second material is less stable at manufacturing environmental conditions (e.g., the processing conditions discussed below) than the first material. The “second material” comprises a porogen and the “first material” comprises a matrix polymer. The invention then forms conductive features in the dielectric layer and removes (e.g., by heating) the second material from the dielectric layer to create air pockets in the interconnection layer where the second material was positioned.

The conductive features are formed by patterning the dielectric layer to create a pattern of grooves and openings, forming a conductor material over the dielectric layer, and polishing the dielectric layer to allow the conductor material to remain only in the pattern of grooves and openings. Before the conductor material is formed, the invention lines the pattern of grooves and openings with a liner material. The removing of the second material leaves the conductor material and the liner material unaffected.

The structure produced by the invention is an integrated circuit structure that comprises at least one first layer comprising logical and functional devices and least one interconnection layer above the first layer. The interconnection layer comprises a porous dielectric, conductive features within the dielectric, and a liner lining the conductive features and separating the conductive features from the dielectric. Pores within the porous dielectric are adjacent the liner and the liner is continuous around the conductive features and separates the conductive features from the pores. The pores leave the liner unaffected. The pores contain air such that some portions of the liner are adjacent the air pockets. The liner is completely continuous around the conductive feature and along the pores, such that the liner separates air in the pores from the conductive features. There is a cap material below the dielectric, wherein the dielectric has a lower dielectric constant than the cap material. The conductive features comprise contacts and wiring.

Since the formation of the liner is completed before the porogen is removed, the liner will maintain its position and shape during the curing process. Thus, even if pores form next to the liner, this will not affect the liner's performance because the liner will remain in place and prevent the conductor from diffusing. Such would not be the case if the liner were formed after the pores were created because it might be impossible to fill small sidewall pores with liner material, which would cause a gap in the liner, and which would allow the conductor material to diffuse into the low K dielectric. Therefore, the invention allows the dielectric constant of low K dielectrics to be reduced with the inclusion of pores formed with a porogen. The invention allows the liner that lines the trenches and sidewalls to be formed (and maintained) properly (even in the presence of such pores) so that the liner can prevent the conductor from diffusing into the low K dielectric.

### BRIEF DESCRIPTION OF THE DRAWINGS

The invention will be better understood from the following detailed description of a preferred embodiment(s) of the invention with reference to the drawings, in which:

FIG. 1 is a schematic diagram illustrating an interconnect structure after a polishing process;

FIG. 2 is a schematic diagram illustrating the same interconnect structure shown in FIG. 1, after porogen burn out;

FIG. 3A is a schematic diagram illustrating an enlarged portion of a defective junction between the conductor, liner, and porous dielectric;

FIG. 3B is a schematic diagram illustrating an enlarged portion of the junction between the conductor, liner, and porous dielectric shown in FIG. 2; and

FIG. 4 is a flow diagram of the inventive process.

### DETAILED DESCRIPTION OF PREFERRED EMBODIMENTS OF THE INVENTION

As mentioned above, low K dielectrics are very useful in integrated circuit structures, such as BEOL interconnection layers. To further reduce the dielectric constant of the low K insulating material, porogen (e.g., a pore generating material) can be embedded into the low K dielectric material while coating. The porogen is burned out to create pores in the dielectric material to further reduce the effective dielectric constant. However, after the dry etch process to pattern the dielectric material, the pores may be located at the side walls of the etched trenches. The subsequent liner layer deposition may not cover all pores in the side walls. This will cause a reliability problem if the conductor filled in the trench diffuses into the porous low K material (causing the circuit to fail).

Therefore, as described below, one aspect of the invention burns the porogen out only after the metalization process is completed, such that the liner coverage is not affected by pores in the trench side walls. The invention either selects the polishing mask to be permeable to the porogen or removes the polishing mask to allow the porogen to diffuse out during heating.

Since the formation of the liner is completed before the porogen is removed, the liner will maintain its position and shape during the curing process. Thus, even if pores form next to the liner, this will not affect the liner's performance because the liner will remain in place and prevent the conductor from diffusing. Such would not be the case if the liner were formed after the pores were created because it might be impossible to fill small sidewall pores with liner material, which would cause a gap in the liner, and which would allow the conductor material to diffuse into the low K dielectric. Therefore, the invention allows the dielectric constant of low K dielectrics to be reduced with the inclusion of pores formed with a porogen (without suffering diffusion problems). The invention allows the liner that lines the trenches and sidewalls to be formed (and maintained) properly (even in the presence of such pores) so that the liner can prevent the conductor from diffusing into the low K dielectric.

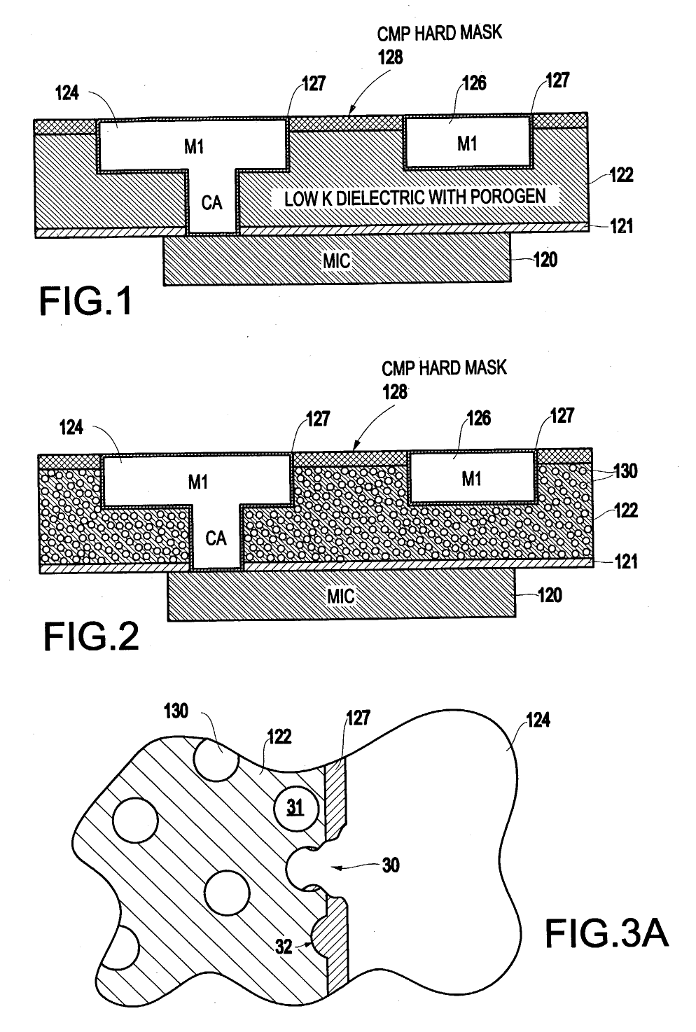

More specifically, FIG. 1 illustrates a portion of an integrated circuit structure that includes an underlying layer 120 and an interconnection layer 122 that is the subject of the invention. The underlying layer 120 can comprise a portion of the FEOL logical and functional device containing layer, or can comprise another one of the multiple interconnect layers that will be included within the BEOL structure. The low K dielectric layer is shown as item 122 and is properly separated from the underlying layer 120 by some form of cap layer 121. As mentioned above, the dielectric layer 122 includes a porogen. The metallic features (wires, interconnects, vias, studs, etc.) are shown as items 124 and 126 and are lined by a liner 127. The liner 127 prevents the conductor 124, 126 from diffusing into the low K dielectric 122. The chemical mechanical polishing (CMP) hard mask is shown as item 128. FIG. 2 illustrates the same structure after the curing process which creates air pockets (pores, openings, etc.) 130, yet does not affect the liner 127.

One exemplary method for achieving such structures is discussed below. One ordinarily skilled in the art would understand (after reviewing this disclosure) that many other similar processes/materials could be used to achieve the same result and the invention is not limited to the following process and materials. The dielectric material 122 can be spin-coated at spin speeds ranging between 900 and 4500 rpm (preferably 3000 rpm) on the underlying cap layer 121. The level dielectric material 122 can contain a matrix polymer and a porogen. The porogen could comprise but not limited to any substance that is less thermally stable than the remaining dielectric such as poly(propylene oxide), poly(methyl methacrylate), aliphatic polyesters, polylactones, polycaprolactones, polyethylene glycol polyvalerolactone, polyvinylpyridines, etc. The matrix polymer is thermally more stable than the porogen. The matrix material could comprise, but is not limited to polyarylene ethers, polyarylenes, polybenzazoles, benzocyclobutenes, polycyanurates, SiLK, etc. Porous materials of this kind are described in Patent Cooperation Treaty International Patent Application WO 00/31183 entitled “A composition containing a cross-linkable matrix precursor and a porogen, and a porous matrix prepared therefrom” by Kenneth, J. Bruza et al. which is assigned to The Dow Chemical Company, USA, the contents of which are incorporated herein in their entirety by reference. After spin-coating, the dielectric material 122 is hot-plate baked at a temperature between 150 C and 400 C, preferably 300 C, in order to partially-crosslink the polymers with other dielectric materials, while the porogen remains intact. This crosslinking makes the dielectric material impenetrable to solvents contained in the spin-on hardmask material.

The low-k CMP hardmask 128 that is permeable to porogen-like materials, is spin-coated on the same track, and within the same run as the porogen-containing dielectric material. The hardmask material 128 is a polymeric material (inorganic in composition), and can be spin-coated. Examples of the hardmask include, methylsilsesquioxanes, phenylsilsesquioxanes, and similar materials. The CMP hardmask is applied on the same instrument as the temporary dielectric layer by spin coating at spin speeds between 900 and 4500 rpm (preferably 1500-2000 rpm). This material is then hot-plate baked at temperatures between 150 C and 400 C, preferably 300 C, to crosslink the material, and create a stable, sound film that can withstand lithography, etching, and metallization.

Both the porogen-containing dielectric layer 122 and the CMP hardmask 128 are coated with photoresist, exposed, and patterned with the metal level lithography (either single or dual damascene). The porogen-containing dielectric layer 122 and CMP hardmask 128 are then etched to form the lines and vias using, for example, an N₂/H₂, O₂, or fluorocarbon chemistry, depending on the chemical makeup of the porogen-containing dielectric layer. The lines and vias are then lined with the liner material 127 that is compatible with the porogen-containing dielectric material 122. The adhesion of the liner 127 to the dielectric material 122 must be sufficient to not delaminate during CVD, and further processing. The conductor 124, 126 (e.g., metal, polysilicon, alloy, etc.) is then formed using any well-known conventional formation process (sputtering, CVD, etc.).

The entire structure (dielectric layer, permeable spin-on CMP hardmask) undergoes chemical-mechanical polishing (CMP), with a liner and Cu polish that is compatible with the porogen-containing dielectric material, and hardmask material. Downforces should be between 1 psi and 9 psi (preferably 3-5 psi) as to not cause delamination. This is to planarize the hardmask surface 128.

The entire structure (porogen-containing dielectric layer 122, permeable CMP hardmask, 128, conductor 124, 126, etc.) is then furnace cured. The cure process ramps the structure at rates from 3-50 C/min, preferably 5 C/min to cure temperatures ranging from 350 to 450 C, preferably (415 C). The structure is then held isothermally at the cure temperatures for 60-180 minutes (preferably 120 minutes) to allow for the decomposition and outgassing of thermally liable materials (e.g., the porogen) through the entire structure, including the CMP hardmask. During this process, the thermally liable porogen decomposes, and outgasses, leaving behind pores in the matrix dielectric material. This process can be repeated several times to generate multilevel structures.

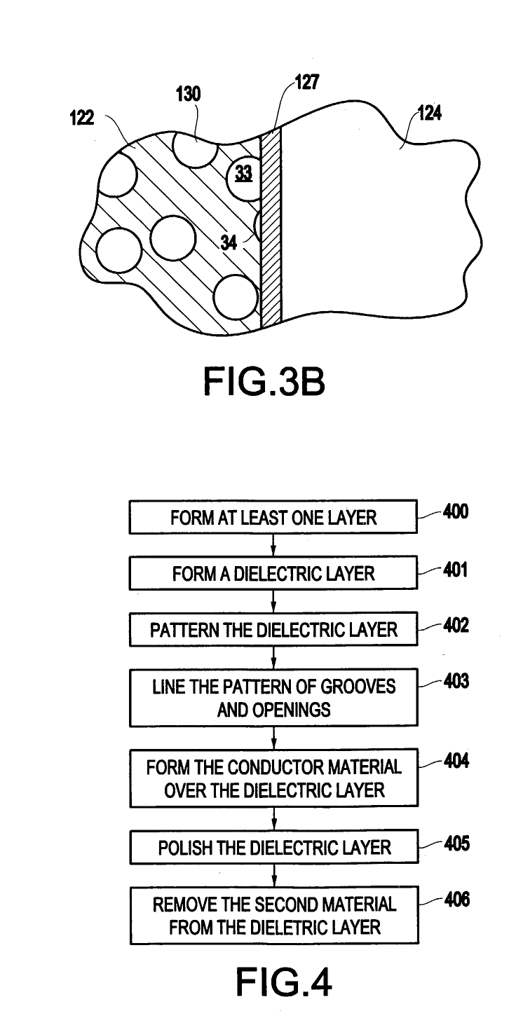

FIGS. 3A and 3B are schematic diagrams illustrating an enlarged view of a portion of the junction between the conductor 124, liner 127, and porous dielectric 122 containing pores (air gaps) 130. FIG. 3A illustrates a defective structure that includes a region 30 where the liner is discontinuous (breached) and where the conductor 124 is in direct contact with the low K dielectric 122. This is the structure that may be produced if the pores are formed before the dielectric 122 is patterned, as discussed above. The structure shown in FIG. 3A is disadvantageous because the conductor material 124 will diffuse into the low K dielectrics 122 through the breach 30, thereby short circuiting the interconnect layer. Note that any pore or partial pore (such as pore 32) that is formed on the sidewall of the conductor trench will be filled with the liner material 127 (or will form a breach of the liner 30) and that only pores that has some physical separation from the sidewall (for example pore 31) will contain air.

To the contrary, FIG. 3B illustrates an enlarged view of a portion of the structure shown in FIG. 2 that is formed by the inventive process of removing the porogen material only after the liner 127 and conductor 124 are in place. With the structure shown in FIG. 3B, the pores 130 do not affect the continuity of the liner 127 because the liner 127 was formed before the pores 130 were formed. Therefore, with the structure shown in FIG. 3B there will not be breaches (such as the breach 30) in the liner 127 and the liner 127 will be completely continuous. Further, with the structure shown in FIG. 3B, air within some pores will actually comes in contact with the liner 127 (e.g., pores 33-34). Note that this situation is impossible with the structure shown in FIG. 3A because pores along the sidewall of the conductor trench will either be filled with the liner material (pore 32) or will create breaches (breach 30).

Thus, the structure produced by the invention (shown in FIG. 3B) is an integrated circuit structure that comprises at least one first layer 120 comprising logical and functional devices and least one interconnection layer 122 above the first layer. The interconnection layer comprises a porous dielectric 122, conductive features 124, 126 within the dielectric, and a liner 127 lining the conductive features and separating the conductive features from the dielectric. Pores 130 within the porous dielectric are adjacent the liner and the liner is continuous around the conductive features and separates the conductive features from the pores. The pores leave the liner unaffected. The pores (33, 34) contain air, such that some portions of the liner are adjacent air. The liner is completely continuous around the conductive feature and along the pores, such that the liner separates air in the pores from the conductive features.

The invention is shown in flowchart form in FIG. 4. More specifically, the invention forms at least one first layer 400 (comprising logical and functional devices) and forms at least one interconnection layer 401-406 above the first layer. The interconnection layer is adapted to form electrical connections between the logical and functional devices.

The interconnection layer is made by first forming a dielectric layer 401. The dielectric layer includes a first material and a second material, wherein the second material is less stable at manufacturing environmental conditions (e.g., the processing conditions discussed above) than the first material. The “second material” comprises a porogen and the “first material” comprises a matrix polymer. The invention then forms conductive features 402-405 in the dielectric layer and removes (e.g., by heating) 406 the second material from the dielectric layer to create air pockets in the interconnection layer where the second material was positioned.

The conductive features are formed by patterning the dielectric layer 402 to create a pattern of grooves and openings in the dielectric layer. Before the conductor material is formed, the invention lines the pattern of grooves and openings 404 with a liner material. The invention then forms the conductor material over the dielectric layer 404, and polishes the dielectric layer 405 to allow the conductor material to remain only in the pattern of grooves and openings. The removing of the second material 406 leaves the conductor material and the liner material unaffected.

Since the formation of the liner 127 is completed before the porogen is removed, it will maintain its position and shape during the curing process. Thus, even if a pore 130 forms next to the liner 127, this will not affect the liner's performance because the liner will remain in place and prevent the conductor 124, 126 from diffusing. At most, pores may border the liner, but the continuity of the liner would not be disturbed. Such would not be the case if the liner 127 were formed after the pores 130 were created because it might be impossible to fill small sidewall pores with liner material, which would cause a gap in the liner 127, and which would allow the conductor 124, 126 material to diffuse into the low K dielectric. Therefore, the invention allows the dielectric constant of low K dielectrics to be reduced with the inclusion of pores formed with a porogen. The invention allows the liner that lines the trenches and sidewalls to be formed (and maintained) properly (even in the presence of such pores) so that the liner can prevent the conductor from diffusing into the low K dielectric.

While the invention has been described in terms of preferred embodiments, those skilled in the art will recognize that the invention can be practiced with modification within the spirit and scope of the appended claims.

What is claimed is:

1. An integrated circuit structure comprising:
at least one first layer comprising logical and functional devices; and
and least one interconnection layer above said first layer,
wherein said interconnection layer comprises:
a porous dielectric;
conductive features within said dielectric; and
a liner lining said conductive features and separating said conductive features from said dielectric,
wherein pores within said porous dielectric are adjacent said liner and said liner is continuous around said conductive features and separates said conductive features from said pores.

2. The structure in claim 1, wherein said pores leave said liner unaffected.

3. The structure in claim 1, wherein said pores contain air such that some portions of said liner are adjacent air.

4. The structure in claim 3, wherein said liner is completely continuous around said conductive feature and along said pores such that said liner separates air in said pores from said conductive features.

5. The structure in claim 1, further comprising a cap material below said dielectric, wherein said dielectric has a lower dielectric constant than said cap material.

6. The structure in claim 1, wherein said conductive features comprise contacts and wiring.

7. An interconnection layer for use in an integrated circuit structure, said interconnection layer comprising:
a porous dielectric;
conductive features within said dielectric; and
a liner lining said conductive features and separating said conductive features from said dielectric,
wherein pores within said porous dielectric are adjacent said liner and said liner is continuous around said conductive features and separates said conductive features from said pores.

8. The structure in claim 7, wherein said pores leave said liner unaffected.

9. The structure in claim 7, wherein said pores contain air such that some portions of said liner are adjacent air.

10. The structure in claim 9, wherein said liner is completely continuous around said conductive feature and along said pores such that said liner separates air in said pores from said conductive features.

11. The structure in claim 7, further comprising a cap material below said dielectric, wherein said dielectric has a lower dielectric constant than said cap material.

12. The structure in claim 7, wherein said conductive features comprise contacts and wiring.

13. A method of forming an integrated circuit structure, said method comprising:
forming at least one logical/functional layer; and
forming at least one interconnection layer above said logical/functional layer,
wherein said forming of said interconnection layer comprises:
forming a dielectric layer, wherein said dielectric layer includes a first material and a second material, wherein said second material is less stable than said first material;
forming conductive features in said dielectric layer; and
removing said second material from said dielectric layer to create pores in said interconnection layer.

14. The method in claim 13, wherein said removing process comprises a heating process.

15. The method in claim 13, wherein said forming of said conductive features comprises:
patterning said dielectric layer to create a pattern of grooves and openings in said dielectric layer;
forming a conductor material over said dielectric layer; and
polishing said dielectric layer to allow said conductor material to remain only in said pattern of grooves and openings.

16. The method in claim 15, further comprising, before said forming of said conductor material, lining said pattern of grooves and openings with a liner material.

17. The method in claim 16, wherein said removing of said second material leaves said conductor material and said liner material unaffected.

18. The method in claim 13, wherein said second material comprises a porogen.

19. The method in claim 13, wherein said first material comprises a matrix polymer.

20. A method of forming an integrated circuit structure, said method comprising:
forming at least one first layer comprising logical and functional devices; and
forming at least one interconnection layer above said first layer, said interconnection layer being adapted to form electrical connections between said logical and functional devices,
wherein said forming of said interconnection layer comprises:
forming a dielectric layer, wherein said dielectric layer includes a first material and a second material, wherein said second material is less stable at manufacturing environmental conditions than said first material;
forming conductive features in said dielectric layer; and
removing said second material from said dielectric layer to create pores in said interconnection layer where said second material was positioned.
